(19) United States
(12) Patent Application Publication
(10) Pub. No.: US 2014/0028331 A1
(43) Pub. Date: Jan. 30, 2014

(54) INDUCTANCE MEASUREMENT CIRCUIT

(71) Applicants: HON HAI PRECISION INDUSTRY CO., LTD., New Taipei (TW); HONG FU JIN PRECISION INDUSTRY (ShenZhen) CO.,LTD., Shenzhen (CN)

(72) Inventors: YUN BAI, Shenzhen (CN); PENG CHEN, Shenzhen (CN); SONG-LIN TONG, Shenzhen (CN)

(73) Assignees: HON HAI PRECISION INDUSTRY CO., LTD., New Taipei (TW); HONG FU JIN PRECISION INDUSTRY (ShenZhen) CO.,LTD., Shenzhen (CN)

(21) Appl. No.: 13/947,145

(22) Filed: Jul. 22, 2013

(30) Foreign Application Priority Data
Jul. 26, 2012 (CN) 2012102611814

(51) Int. Cl. G01R 27/26

(52) U.S. Cl. CPC G01R 27/2611
USPC 324/654

(57) ABSTRACT

An inductance measurement circuit includes a control circuit, a constant current supply circuit, a voltage detecting circuit, and a display circuit. The control circuit controls the constant current supply circuit to supply a first current for a first inductor. The control circuit controls the voltage detecting circuit to detect a voltage on the first inductor. The control circuit obtains an internal resistance of the first inductor by dividing the first voltage by the first constant current. The display circuit displays the internal resistance of the first inductor.

### BACKGROUND

1. Technical Field

The present disclosure relates to a circuit for measuring inductance of inductors.

2. Description of Related Art

Coupling inductors are commonly used in booster circuits to reduce number of output capacitors, thereby reducing cost. However, there are no common test instruments to measure inductance of the coupling inductors except by manual measurement.

Therefore, there is room for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is a block diagram of an embodiment of an inductance measurement circuit of the present disclosure, where the inductance measurement circuit includes a control circuit, a constant current supply circuit, a voltage detecting circuit, and a display circuit.

FIG. 2 is a circuit diagram of the control circuit of FIG. 1.

FIG. 3 is a circuit diagram of the constant current supply circuit of FIG. 1.

FIG. 4 is a circuit diagram of the voltage detecting circuit of FIG. 1.

FIG. 5 is a circuit diagram of the display circuit of FIG. 1.

### DETAILED DESCRIPTION

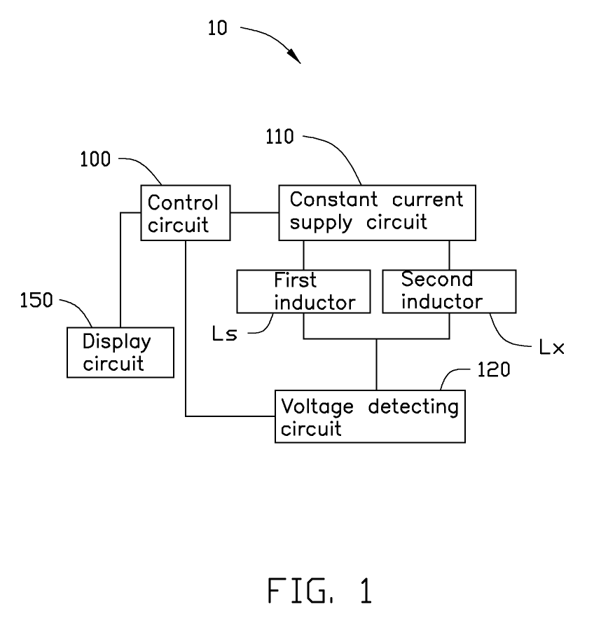

FIG. 1 shows an embodiment of an inductance measurement circuit 10 of the present disclosure.

The inductance measurement circuit 10 includes a control circuit 100, a constant current supply circuit 110, a voltage detecting circuit 120, and a display circuit 150. In this embodiment, the constant current supply 110 supplies constant current for a first inductor Ls and a second inductor Lx.

The control circuit 100 is connected to the constant current supply circuit 110 to control the constant current supply circuit 110 to supply constant current for the first inductor Ls and the second inductor Lx. The control circuit 100 is also connected to the voltage detecting circuit 120 to control the voltage detecting circuit 120 to detect voltage across the first inductor Ls and the second inductor Lx. Based on the current and the voltage, the control circuit 100 can obtain internal resistance (direct current resistance (DCR)) of the first inductor Ls and the second inductor Lx.

The display circuit 150 is connected to the control circuit 100 to display the internal DCR of the first inductor Ls and the second inductor Lx.

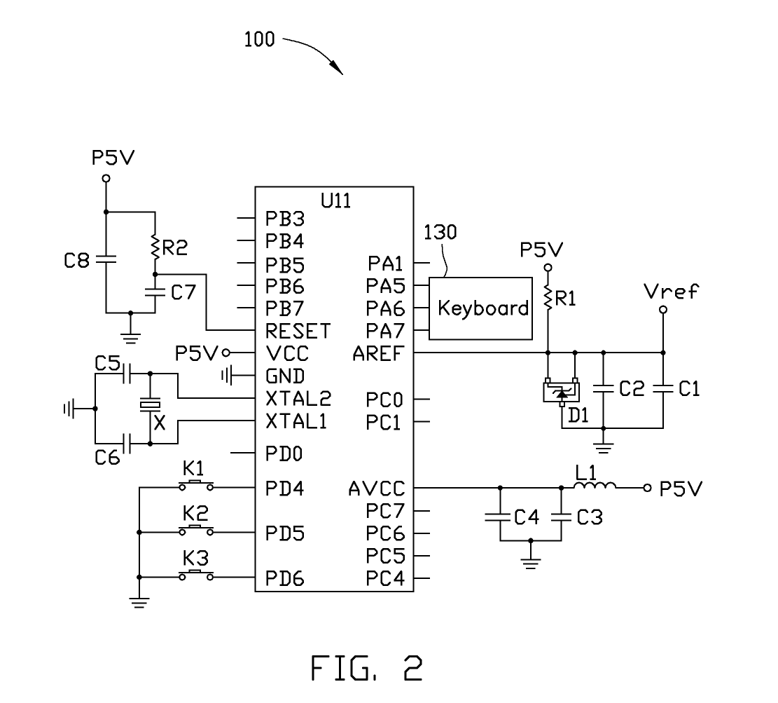

FIG. 2 is a circuit diagram of the control circuit 100. The control circuit 100 includes a single chip microcomputer (SCM) U11. A first group of input output (I/O) pins PB3-PB7 of the SCM U11 output control signals. A pin PA1 of a second group of I/O pins of the SCM U11 is connected to the voltage detecting circuit 120. Pins PA5-PA7 of the second group of I/O pins are connected to a keyboard 130. A power pin AREF of the SCM U11 is connected to a power source P5V through a resistor R1. The power pin AREF is also connected to a cathode and a control electrode of a Schottky diode D1. An anode of the Schottky diode D1 is grounded. The power pin AREF is further connected to a power source Vref. The power source Vref is grounded through capacitors C1 and C2 connected in parallel. A power pin AVCC of the SCM U11 is connected to the power source P5V through an inductor L1. The power pin AVCC is also grounded through capacitors C3 and C4 connected in parallel.

A third group of I/O pins PC4-PC7 of the SCM U11 are connected to the display circuit 150. Pin PC0 and pin PC1 of the SCM U11 are connected to the constant current supply circuit 110. A fourth group of I/O pins PD4-PD6 of the SCM U11 are grounded through switches K1-K3, respectively. Clock pins XTAL1 and XTAL2 of the SCM U11 are connected to first and second ends of a crystal oscillator X. The first and second ends of the crystal oscillator are grounded through capacitors C5 and C6, respectively. A power pin VCC of the SCM U11 is connected to the power source P5V. A reset pin RESET of the SCM U11 is connected to the power source P5V through a resistor R2. The reset pin RESET is also grounded through a capacitor C7. The power source P5V is grounded through a capacitor C8.

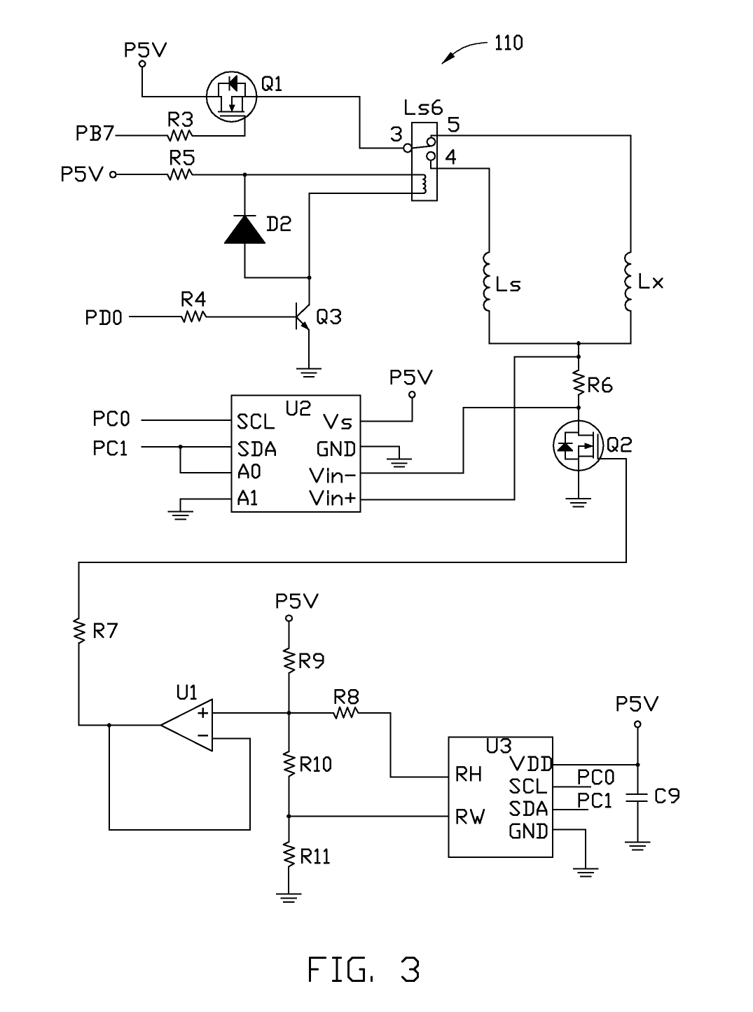

FIG. 3 is a circuit diagram of the constant current supply circuit 110. The constant current supply circuit 110 includes a metallic oxide semiconductor field-effect transistor (MOSFET) Q1, a MOSFET Q2, a transistor Q3, a relay LS6, a comparator U1, a current stabilization chip U2, and a digital potentiometer U3. A gate of the MOSFET Q1 is connected to the pin PB7 of the SCM U11 through a resistor R3. A drain of the MOSFET Q1 is connected to the power source P5V. A source of the MOSFET Q1 is connected to a first end 3 of a pole of a switch of the relay LS6.

A base of the transistor Q3 is connected to a pin PD0 of the SCM U11 through a resistor R4. An emitter of the transistor Q3 is grounded. A collector of the transistor Q3 is connected to an anode of a diode D2, and connected to a first end of a coil of the relay LS6. A second end of the coil of the relay LS6 is connected to a cathode of the diode D2. The cathode of the diode D2 is connected to the power source P5V through a resistor R5. A first throw 4 of the switch of the relay LS6 is connected to a drain of the MOSFET Q2 through the first inductor Ls and the resistor R6 in that order. A second throw 5 of the switch of the relay LS6 is connected to a node between the first inductor Ls and the resistor R6 through the second inductor Lx.

A clock pin SCL of the current stabilization chip U2 is connected to the pin PC0 of the SCM U11. A data pin SDA of the current stabilization chip U2 is connected to the pin PC1 of the SCM U11. An address pin A0 of the current stabilization chip U2 is connected to the data pin SDA. An address pin A1 of the current stabilization chip U2 is grounded. A power pin Vs of the current stabilization chip U2 is connected to the power source P5V. A ground pin GND of the current stabilization chip U2 is grounded. A positive voltage pin Vin+ of the current stabilization chip U2 is connected to a node between the first inductor Ls and the R6. A negative voltage pin of the current stabilization chip U2 Vin− is connected to the drain of the MOSFET Q2.

A source of the MOSFET Q2 is grounded. A gate of the MOSFET Q2 is connected to an output of the comparator U1 through a resistor R7. The output of the comparator U1 is connected to an inverting input of the comparator U1. A non-inverting input of the comparator U1 is connected to a pin RH of the digital potentiometer U3 through a resistor R8. The non-inverting input of the comparator U1 is connected to the power source P5V through a resistor R9. The non-inverting input of the comparator U1 is grounded through a resistor R10 and a resistor R11 in that order. A node between the resistor R10 and the resistor R11 is connected to a slide pin RW of the digital potentiometer U3. A power pin VDD of the digital potentiometer U3 is connected to the power source P5V. The power pin VDD of the digital potentiometer U3 is also grounded through a capacitor C9. A ground pin GND of the digital potentiometer U3 is grounded. A clock pin SCL of the digital potentiometer U3 is connected to the pin PC0 of the SCM U11. A data pin SDA of the digital potentiometer U3 is connected to the pin PC1 of the SCM U11.

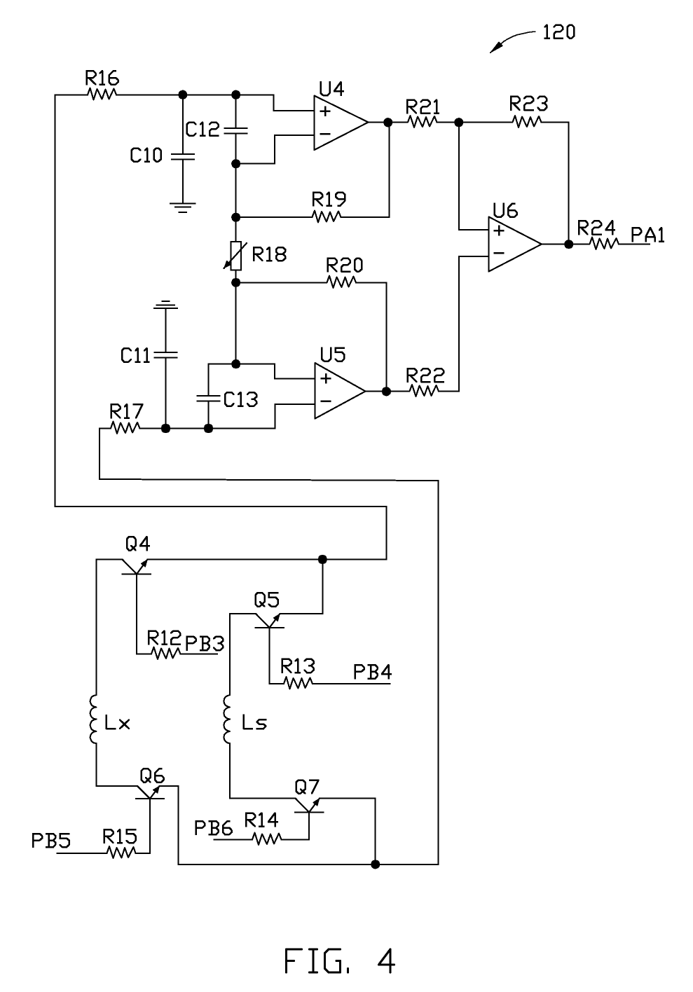

FIG. 4 is a circuit diagram of the voltage detecting circuit 120. The voltage detecting circuit 120 includes transistors Q4-Q7 and operational amplifiers U4-U6. A base of the transistor Q4 is connected to the pin PB3 of the SCM U11 through a resistor R12. An emitter of the transistor Q4 is connected to an emitter of the transistor Q5. A base of the transistor Q5 is connected to the pin PB4 of the SCM U11. A collector of the transistor Q5 is connected to a collector of the transistor Q7 through the first inductor Ls. A base of the transistor Q7 is connected to the pin PB6 of the SCM U11. A collector of the transistor Q4 is connected to a collector of the transistor Q6 through the inductor Lx. A base of the transistor Q6 is connected to the pin PB5 of the SCM U11. An emitter of the transistor Q6 is connected to an emitter of the transistor Q7.

The emitters of the transistors Q4 and Q5 are also connected to a non-inverting input of the operational amplifier U4 through a resistor R16. A node between the non-inverting input of the operational amplifier U4 and the resistor R16 is grounded through a capacitor C10. The emitters of the transistors Q6 and Q7 are also connected to an inverting input of the operational amplifier U5 through a resistor R17. A node between the inverting input of the operational amplifier U5 and the resistor R17 is grounded through a capacitor C11. The non-inverting input of the operational amplifier U4 is connected to an inverting input of the operational amplifier U4 through a capacitor C12. A non-inverting input of the operational amplifier U5 is connected to the inverting input of the operational amplifier U5 through a capacitor C13.

The inverting input of the operational amplifier U4 is connected to the non-inverting input of the operational amplifier U5 through a trimming resistor R18. An output of the operational amplifier U4 is connected to the inverting input of the operational amplifier U4 through a resistor R19. An output of the operational amplifier U5 is connected to the non-inverting input of the operational amplifier U5 through a resistor R20.

The output of the operational amplifier U4 is also connected to a non-inverting input of the operational amplifier U6 through a resistor R21. The output of the operational amplifier U5 is also connected to an inverting input of the operational amplifier U6 through a resistor R22. An output of the operational amplifier U6 is connected to the non-inverting input of the operational amplifier U6 through a resistor R23, and also connected to the pin PA1 of the SCM U11 through a resistor R24.

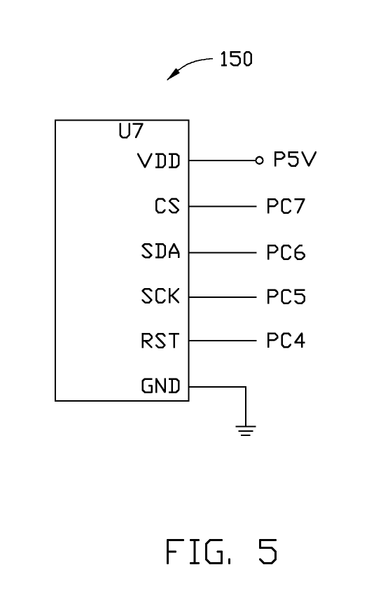

FIG. 5 is a circuit diagram of the display circuit 150. The display circuit 150 includes a display U7. A power pin VDD of the display U7 is connected to the power source P5V. Data pins CS, SDA, SCK, and RST are connected to the pins PC7, PC6, PC5, and PC4 of the SCM U11, respectively. A ground pin GND of the display U7 is grounded.

The working principle of the inductance measurement circuit 10 is described below.

The pins PA5-PA7 receive input signals from the keyboard 130. The pins PD4-PD6 receive input signals from switches K1-K3. The SCM U11 outputs corresponding control signals to the MOSFET Q1 and the transistor Q3 of the constant current supply circuit 110 based on the input signals from the switches K1-K3 and the keyboard 130 to obtain the internal resistances of the first inductor Ls or the second inductor Lx. In this embodiment, when the switches K1-K3 are turned on, the pins PD4-PD6 are grounded and the SCM U11 outputs a high level signal through the pin PD0. When the switches K1-K3 are turned off, the pins PD4-PD6 are disconnected from ground and the SCM U11 outputs a low level signal through the pin PD0. The pin PB7 outputs high or low level signals according to the signals inputted through the keyboard.

To measure the internal resistance of the first inductor Ls, the input signals from the switches K1-K3 and the keyboard 130 control the SCM U11 to output high level signals from the pin PB7 and the pin PD0. The MOSFET Q1 and the transistor Q3 are turned on. The first end 3 of the pole of the relay LS6 is connected to the first throw 4 of the switch of the relay LS6. The power source P5V is connected to the first inductor Ls through the MOSFET Q1 and the relay LS6 in that order. The current stabilization chip U2 and the digital potentiometer U3 are used to connect different resistors to the first inductor Ls to change the amount of current flowing through the first inductor Ls. In this embodiment there are three different current, I1, I2, and I3, flowing through the first inductor Ls by adjusting the digital potentiometer U3. In another embodiment, the internal resistance of the first inductor Ls can be obtained by not more than two different current flowing through the first inductor Ls. The SCM U11 outputs low level signals through the pin PB3 and the pin PB5. The SCM U11 outputs high level signals through the pin PB4 and the pin PB6. The transistors Q4 and Q6 are turned off. The transistors Q5 and Q7 are turned on. The first inductor Ls is then connected to the voltage detecting circuit 120. The voltage on the first inductor Ls is inputted to the SCM U11 after being processed by the operational amplifiers U4-U6. The voltages on the first inductor Ls will be V1, V2, and V3 when the current in the first inductor Ls corresponds to I1, I2, and I3, respectively. The internal resistance of the first inductor Ls will be: DCR=(V1+V2+V3)/(I1+I2+I3).

The measurement process on the second inductor Lx is similar to that for the first inductor Ls. According to the input signals from the keyboard 130 and from the switches K1-K3 the SCM U11 outputs high level signals through the pin PB7 and outputs low level signals through the pin PD0. The MOSFET Q1 is turned on and the transistor Q3 is turned off. The first end 3 of the pole of the relay LS6 is connected to the second throw 5. The power source P5V is connected to the second inductor Lx through the MOSFET Q1 and the relay LS6 in that order. The current stabilization chip U2 and the digital potentiometer U3 are used to connect different resistors to the second inductor Lx to change the amount of current flowing through the second inductor Lx. In this embodiment there are three different current, I11, I12, and I13, flowing through the second inductor Lx by adjusting the digital potentiometer U3. The SCM U11 outputs low level signals through the pin PB4 and the pin PB6. The SCM U11 outputs high level signals through the pin PB3 and the pin PB5. The transistors Q4 and Q6 are turned on. The transistors Q5 and Q7 are turned off. The second inductor Lx is then connected to the voltage detecting circuit 120. The voltage on the second inductor Lx is inputted to the SCM U11 after being processed by the operational amplifiers U4-U6. The voltages on the second inductor Lx will be V11, V12, and V13 when the current in the second inductor Lx corresponds to I11, I12, and I13, respectively. The internal resistance of the second inductor Lx will be: DCR=(V11+V12+V13)/(I11+I12+I13).

The SCM U11 outputs the internal resistances of the first inductor Ls and the second inductor Lx to the display U7. The display U7 displays the internal resistances of the first inductor Ls and the second inductor Lx.

While the disclosure has been described by way of example and in terms of preferred embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. An inductance measurement circuit for a first inductor, comprising:
a control circuit;
a constant current supply circuit connected to the control circuit, wherein the constant current supply circuit is controlled by the control circuit to supply a first constant current for the first inductor;
a voltage detecting circuit connected to the control circuit, wherein the voltage detecting circuit is controlled by the control circuit to detect a voltage across the first inductor; and
a display circuit connected to the control circuit, to display an internal resistance of the inductor using the voltage across the first inductor.

2. The inductance measurement circuit of claim 1, wherein the control circuit controls the constant current supply circuit to further supply a second constant current for the first inductor.

3. The inductance measurement circuit of claim 2, wherein the control circuit controls the constant current supply circuit to further supply a third constant current for the first inductor

4. The inductance measurement circuit of claim 2, wherein the control circuit comprises a single chip microcomputer (SCM), wherein first to fifth pins of a first group of input output (I/O) pins of the SCM are used to output control signals, a first pin of a second group of I/O pins of the SCM is connected to the voltage detecting circuit, second to fourth pins of the second group of I/O pins of the SCM are connected to a keyboard, a first power pin of the SCM is connected to a first power source through a first resistor, and the first power pin is also connected to a cathode and a control electrode of a Schottky diode, an anode of the Schottky diode is grounded, the first power pin is also connected to a second power source, the second power source is grounded through a first capacitor, a second power pin of the SCM is connected to the first power source through a second inductor, the second power pin is grounded through a second capacitor, first and second pins of a third group of I/O pins of the SCM are connected to the constant current supply circuit, third to sixth pins of the third group of I/O pins of the SCM are connected to the display circuit, a first pin of a fourth group of I/O pins of the SCM is connected to the constant current supply circuit, second to fourth pins of the fourth group of I/O pins are grounded through first to third switches, respectively, first and second clock pins of the SCM are connected to first and second ends of a crystal oscillator, the first end of the crystal oscillator is grounded through a third capacitor, the second end of the crystal oscillator is grounded through a fourth capacitor, a third power pin of the SCM is connected to the first power source, a reset pin of the SCM is connected to the first power source through a second resistor, and the reset pin is grounded through a fifth capacitor, the first power source is grounded through a sixth capacitor.

5. The inductance measurement circuit of claim 4, wherein the constant current supply circuit comprises first and second metallic oxide semiconductor field-effect transistors (MOSFETs), a first transistor, a relay, a first operational amplifier, a current stabilization chip, and a digital potentiometer, wherein a gate of the first MOSFET is connected to the fifth pin of the first group of I/O pins of the SCM through a third resistor, a drain of the first MOSFET is connected to the first power source, a source of the first MOSFET is connected to a first end of a pole of a switch of the relay, a base of the first transistor is connected to the first pin of the fourth group of I/O pins of the SCM through a fourth resistor, an emitter of the transistor is grounded, a collector of the transistor is connected to an anode of a diode and connected to a first end of a coil of the relay, a second end of the coil of the relay is connected to a cathode of the diode, the cathode of the diode is connected to the first power source through a fifth resistor, a throw of the switch of the relay is connected to a first end of the first inductor, a second end of the first inductor is connected to a drain of the second MOSFET through a sixth resistor, a clock pin of the current stabilization chip is connected to the first pin of the third group of I/O pins of the SCM, a data pin of the current stabilization chip is connected to the second pin of the third group of I/O pins of the SCM, a first address pin of the current stabilization chip is connected to the data pin, a second address pin of the current stabilization chip is grounded, a power pin of the current stabilization chip is connected to the first power source, a ground pin of the current stabilization chip is grounded, a positive voltage pin of the current stabilization chip is connected to a node between the first inductor and the sixth resistor, a negative voltage pin of the current stabilization chip is connected to the drain of the second MOSFET, a source of the second MOSFET is grounded, a gate of the second MOSFET is connected to an output of the first operational amplifier through a seventh resistor, the output of the first operational amplifier is connected to an inverting input end of the first operational amplifier, a non-inverting input end of the first operational amplifier is connected to the first power source through a ninth resistor, the non-inverting input end of the first operational amplifier is grounded through a tenth resistor and an eleventh resistor in that order, a node between the tenth resistor and the eleventh resistor is connected to a slide pin of the digital potentiometer, a power pin of the digital potentiometer is connected to the first power source, a ground pin of the digital potentiometer is grounded, a clock pin of the digital potentiometer is connected to the first pin of the third group of I/O pins of the SCM, a data pin of the digital potentiometer is connected to the second pin of the third group of I/O pins of the SCM.

6. The inductance measurement circuit of claim 5, wherein the voltage detecting circuit comprises second and third transistors and second to fourth operational amplifiers, a base of the second transistor is connected to the second pin of the first group of I/O pins of the SCM, a base of the third transistor is connected to the fourth pin of the first group of I/O pins of the SCM, a collector of the third transistor is connected to the second end of the first inductor, a collector of the second transistor is connected to the first end of the first inductor, an emitter of the second transistor is connected to a non-inverting input end of the second operational amplifier, an emitter of the third transistor is connected to an inverting input of the third operational amplifier, an inverting input of the second operational amplifier is connected to a non-inverting input of the third operational amplifier through a trimming resistor, an output of the second operational amplifier is connected to the inverting input of the second operational amplifier through a twelfth resistor, an output of the third operational amplifier is connected to the non-inverting input of the third operational amplifier through a thirteen resistor, the output of the third operational amplifier is also connected to an inverting input of the fourth operational amplifier, the output of the second operational amplifier is also connected to a non-inverting input of the fourth operational amplifier, an output of the fourth operational amplifier is connected to the non-inverting input of the fourth operational amplifier through a fourteen resistor, the output of the fourth operational amplifier is connected to the first pin of the second group of I/O pins of the SCM.

7. The inductance measurement circuit of claim 5, wherein the base of the second transistor is connected to the second pin of the first group of I/O pins of the SCM through a fifteen resistor, the base of the third transistor is connected to the fourth pin of the first group of I/O pins of the SCM through a sixteen resistor, the emitter of the second transistor is connected to the non-inverting input end of the second operational amplifier through a seventeen resistor, the emitter of the second transistor is grounded through the seventeen resistor and a seventh capacitor in that order, the emitter of the third transistor is connected to the inverting input of the third operational amplifier through an eighteen resistor, the emitter of the third transistor is grounded through the eighteen resistor and an eighth capacitor in that order, the inverting input of the second operational amplifier is connected to the non-inverting input of the second operational amplifier through a ninth capacitor, the inverting input of the third operational amplifier is connected to the non-inverting input of the third operational amplifier through a tenth capacitor, an output of the second operational amplifier is connected to the non-inverting input of the fourth operational amplifier through a fifteen resistor, the output of the third operational amplifier is connected to the inverting input of the fourth operational amplifier through a sixteen resistor, the output of the fourth operational amplifier is connected to the first pin of the second group of I/O pins of the SCM through a seventeen resistor.

8. The inductance measurement circuit of claim 4, wherein the display circuit comprises a display, a power pin of the display is connected to the first power source, first to fourth data pins are connected to sixth, fifth, fourth, third pins of the third group of I/O pins of the SCM respectively, a ground pin of the display is grounded.
